(19) United States
(12) Patent Application Publication
(10) Pub. No.: US 2026/0068254 A1
(43) Pub. Date: Mar. 5, 2026

(54) SEMICONDUCTOR DEVICE AND METHOD FOR MANUFACTURING SAME

(71) Applicant: Microchip Technology Incorporated, Chandler, AZ (US)

(72) Inventors: Sami El Hageali, Castle Rock, CO (US); Bruce Odekirk, Portland, OR (US); Shesh Mani Pandey, Gilbert, AZ (US); Michael Don Whiteman, Woodland Park, CO (US)

(73) Assignee: Microchip Technology Incorporated, Chandler, AZ (US)

(21) Appl. No.: 19/074,084

(22) Filed: Mar. 7, 2025

Related U.S. Application Data
(60) Provisional application No. 63/690,029, filed on Sep. 3, 2024.

(51) Int. Cl. H10D 62/60; H10D 62/832

(52) U.S. Cl. CPC H10D 62/60; H10D 62/8325

(57) ABSTRACT

A semiconductor device comprising a silicon carbide buffer layer formed within a silicon carbide substrate. A first silicon carbide drift region formed over the silicon carbide buffer layer. A second silicon carbide drift region formed over the first silicon carbide drift region. A third silicon carbide drift region formed over the second silicon carbide drift region.

### CROSS-REFERENCE TO RELATED APPLICATION

The present application claims priority to U.S. Provisional Patent Application No. 63/690,029 filed on Sep. 3, 2024, the contents of which are hereby incorporated by reference in their entirety.

### TECHNICAL FIELD

The present disclosure relates generally to semiconductor substrates for electronic devices, and more specifically to silicon carbide substrates.

### SUMMARY

According to an aspect of one or more examples, there is provided a method of fabricating a semiconductor device. The method may include providing a silicon carbide substrate, forming a silicon carbide buffer layer within the silicon carbide substrate, forming a first silicon carbide drift region over the silicon carbide buffer layer, forming a second silicon carbide drift region over the first silicon carbide drift region, and forming a third silicon carbide drift region over the second silicon carbide drift region. The silicon carbide substrate may comprise a first concentration of a first type dopant and the silicon carbide buffer layer may comprise a second concentration of the first type dopant. The first silicon carbide drift region may comprise a third concentration of the first type dopant. The first concentration and the second concentration may be greater than the third concentration. The third concentration of the first type dopant may increase as a distance from a surface of the silicon carbide substrate increases. The second silicon carbide drift region may comprise a fourth concentration of the first type dopant. The fourth concentration may be greater than the third concentration. The fourth concentration of the first type dopant may increase as the distance from the surface of the silicon carbide substrate increases. The third silicon carbide drift region may comprise a fifth concentration of the first type dopant. The fifth concentration may be greater than the fourth concentration. The fifth concentration of the first type dopant may increase as the distance from the surface of the silicon carbide substrate increases. The first type dopant may comprise an n-type dopant. The first type dopant may comprise a p-type dopant.

According to another aspect of one or more examples, there is provided a semiconductor device. The semiconductor device may include a silicon carbide substrate, a silicon carbide buffer layer formed within the silicon carbide substrate, a first silicon carbide drift region formed over the silicon carbide buffer layer, a second silicon carbide drift region formed over the first silicon carbide drift region, and a third silicon carbide drift region formed over the second silicon carbide drift region. The silicon carbide substrate may comprise a first concentration of a first type dopant and the silicon carbide buffer layer may comprise a second concentration of the first type dopant. The first silicon carbide drift region may comprise a third concentration of the first type dopant. The first concentration and the second concentration may be greater than the third concentration. The third concentration of the first type dopant may increase as a distance from a surface of the silicon carbide substrate increases. The second silicon carbide drift region may comprise a fourth concentration of the first type dopant. The fourth concentration may be greater than the third concentration. The fourth concentration of the first type dopant may increase as the distance from the surface of the silicon carbide substrate increases. The third silicon carbide drift region may comprise a fifth concentration of the first type dopant. The fifth concentration may be greater than the fourth concentration. The fifth concentration of the first type dopant may increase as the distance from the surface of the silicon carbide substrate increases. The first type dopant may comprise an n-type dopant. The first type dopant may comprise a p-type dopant.

### BRIEF DESCRIPTION OF DRAWINGS

FIG. 1A shows a semiconductor device having a silicon carbide substrate with multiple silicon carbide drift layers wherein the concentration of a first type dopant increases continuously in the silicon carbide drift layers as a distance from a surface of the silicon carbide substrate increases and a method of manufacturing the semiconductor device according to one or more examples.

FIG. 1B shows a semiconductor device having a silicon carbide substrate with multiple silicon carbide drift layers wherein the concentration of a first type dopant increases discretely in the silicon carbide drift layers as a distance from a surface of the silicon carbide substrate increases and a method of manufacturing the semiconductor device according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

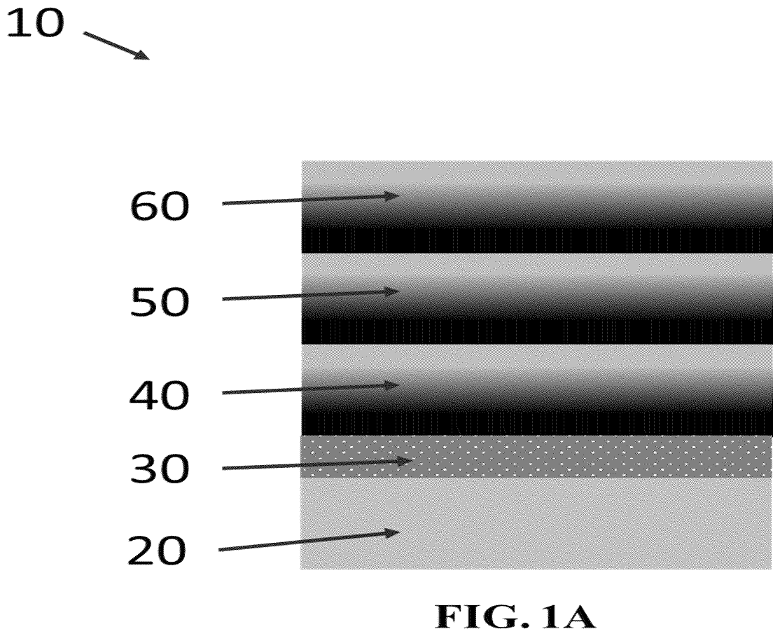

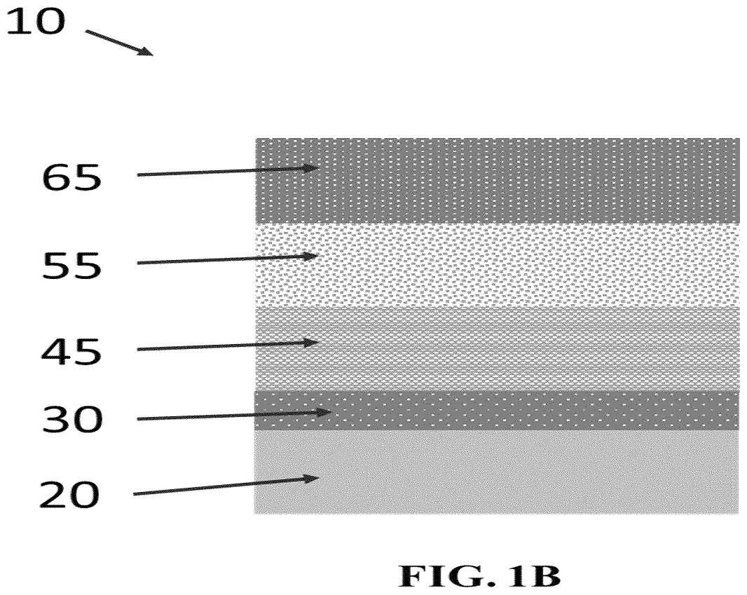

FIG. 1A shows a semiconductor device 10 having a silicon carbide substrate 20 and a method of manufacturing the semiconductor device 10 according to one or more examples. Silicon carbide is often used as a substrate 20 to create many semiconductor devices, and may result in reduced switching losses, higher power density, improved heat dissipation, and increased bandwidth as compared with other materials.

The example semiconductor device 10 of FIG. 1A includes a silicon carbide substrate 20. The silicon carbide substrate 20 shown in FIG. 1A may have a first concentration of a first type dopant, e.g., 5E18 (i.e. 5×10¹⁸). The example semiconductor device 10 of FIG. 1A may include a silicon carbide buffer layer 30 within the silicon carbide substrate 20. The silicon carbide buffer layer 30 may comprise a second concentration of the first type dopant. The example semiconductor device 10 of FIG. 1A may include a first silicon carbide drift region 40 over the silicon carbide buffer layer 30 that may be implanted or intrinsically doped in a dopant chamber. The first silicon carbide drift region 40 may comprise a third concentration of the first type dopant. The third concentration of the first type dopant may increase as a distance from a surface of the silicon carbide substrate 20 increases. The first concentration of the first dopant of the silicon carbide substrate 20 and the second concentration of the first dopant of the silicon carbide buffer layer 30 may be greater than the third concentration of the first dopant of the first silicon carbide drift region 40. The example semiconductor device 10 of FIG. 1A may include a second silicon carbide drift region 50 over the first silicon carbide drift region 40 that may be implanted or intrinsically doped in the dopant chamber. The second silicon carbide drift region 50 may comprise a fourth concentration of the first type dopant. The fourth concentration of the first type dopant may increase as a distance from the surface of the silicon carbide substrate 20 increases. The fourth concentration of the first dopant of the second silicon carbide drift region 50 may be greater than the third concentration of the first dopant of the first silicon carbide drift region 40. The example semiconductor device 10 of FIG. 1A may include a third silicon carbide drift region 60 over the second silicon carbide drift region 50 that may be implanted or intrinsically doped in the dopant chamber. The third silicon carbide drift region 60 may comprise a fifth concentration of the first type dopant. The fifth concentration of the first type dopant may increase as a distance from the surface of the silicon carbide substrate 20 increases. The fifth concentration of the first dopant of the third silicon carbide drift region 60 may be greater than the fourth concentration of the first dopant of the second silicon carbide drift region 50.

In one example of the example semiconductor device 10 of FIG. 1A, the first type dopant may be an n-type dopant. In another example of the example semiconductor device 10 of FIG. 1A, the first type dopant may be a p-type dopant.

FIG. 1B shows a semiconductor device 10 having a silicon carbide substrate 20 and a method of manufacturing the semiconductor device 10 according to one or more examples. Silicon carbide is often used as a substrate 20 to create many semiconductor devices, and may result in reduced switching losses, higher power density, improved heat dissipation, and increased bandwidth as compared with other materials.

The example semiconductor device 10 of FIG. 1B includes a silicon carbide substrate 20. The silicon carbide substrate 20 shown in FIG. 1B may have a first concentration of a first type dopant, e.g., 5E18 (i.e. 5×10¹⁸). The example semiconductor device 10 of FIG. 1B may include a silicon carbide buffer layer 30 within the silicon carbide substrate 20. The silicon carbide buffer layer 30 may comprise a second concentration of the first type dopant. The example semiconductor device 10 of FIG. 1B may include a first silicon carbide drift region 45 over the silicon carbide buffer layer 30 that may be implanted or intrinsically doped in a dopant chamber. The first silicon carbide drift region 45 may comprise a third concentration of the first type dopant. The third concentration of the first type dopant may be continuous throughout the first silicon carbide drift region 45. The first concentration of the first dopant of the silicon carbide substrate 20 and the second concentration of the first dopant of the silicon carbide buffer layer 30 may be greater than the third concentration of the first dopant of the first silicon carbide drift region 45. The example semiconductor device of FIG. 1B may include a second silicon carbide drift region 55 over the first silicon carbide drift region 45 that may be implanted or intrinsically doped in the dopant chamber. The second silicon carbide drift region 55 may comprise a fourth concentration of the first type dopant. The fourth concentration of the first type dopant may be continuous throughout the second silicon carbide drift region 55. The fourth concentration of the first dopant of the second silicon carbide drift region 45 may be greater than the third concentration of the first dopant of the first silicon carbide drift region 45. The example semiconductor device of FIG. 1B may include a third silicon carbide drift region 65 over the second silicon carbide drift region 55 that may be implanted or intrinsically doped in the dopant chamber. The third silicon carbide drift region 65 may comprise a fifth concentration of the first type dopant. The fifth concentration of the first type dopant may be continuous throughout the third silicon carbide drift region 65. The fifth concentration of the first dopant of the third silicon carbide drift region 65 may be greater than the fourth concentration of the first dopant of the second silicon carbide drift region 55.

In one example of the example semiconductor device 10 of FIG. 1B, the first type dopant may be an n-type dopant. In another example of the example semiconductor device 10 of FIG. 1B, the first type dopant may be a p-type dopant.

Various examples have been disclosed herein, in connection with the above description and the drawings. It will be understood that it would be unduly repetitious to literally describe and illustrate every combination and sub-combination of these examples. Accordingly, all examples may be combined in any way and/or combination, and the present specification, including the drawings, shall be construed to constitute a complete written description of all combinations and sub-combinations of the examples described herein, and of the manner and process of making and using them, and shall support claims to any such combination or sub-combination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method of fabricating a semiconductor device, the method comprising:
providing a silicon carbide substrate;
forming a silicon carbide buffer layer within the silicon carbide substrate;
forming a first silicon carbide drift region over the silicon carbide buffer layer;
forming a second silicon carbide drift region over the first silicon carbide drift region; and
forming a third silicon carbide drift region over the second silicon carbide drift region.

2. The method of claim 1, wherein the silicon carbide substrate comprises a first concentration of a first type dopant and the silicon carbide buffer layer comprises a second concentration of the first type dopant.

3. The method of claim 2, wherein the first silicon carbide drift region comprises a third concentration of the first type dopant, the first concentration and the second concentration greater than the third concentration.

4. The method of claim 3, wherein the third concentration of the first type dopant increases as a distance from a surface of the silicon carbide substrate increases.

5. The method of claim 4, wherein the second silicon carbide drift region comprises a fourth concentration of the first type dopant, the fourth concentration greater than the third concentration.

6. The method of claim 5, wherein the fourth concentration of the first type dopant increases as the distance from the surface of the silicon carbide substrate increases.

7. The method of claim 6 wherein the third silicon carbide drift region comprises a fifth concentration of the first type dopant, the fifth concentration greater than the fourth concentration.

8. The method of claim 7, wherein the fifth concentration of the first type dopant increases as the distance from the surface of the silicon carbide substrate increases.

9. The method of claim 8, wherein the first type dopant comprises an n-type dopant.

10. The method of claim 8, wherein the first type dopant comprises a p-type dopant.

11. A semiconductor device comprising:
a silicon carbide substrate;
a silicon carbide buffer layer formed within the silicon carbide substrate;
a first silicon carbide drift region formed over the silicon carbide buffer layer;
a second silicon carbide drift region formed over the first silicon carbide drift region; and
a third silicon carbide drift region formed over the second silicon carbide drift region.

12. The semiconductor device of claim 11, wherein the silicon carbide substrate comprises a first concentration of a first type dopant and the silicon carbide buffer layer comprises a second concentration of the first type dopant.

13. The semiconductor device of claim 12, wherein the first silicon carbide drift region comprises a third concentration of the first type dopant, the first concentration and the second concentration greater than the third concentration.

14. The semiconductor device of claim 13, wherein the third concentration of the first type dopant increases as a distance from a surface of the silicon carbide substrate increases.

15. The semiconductor device of claim 14, wherein the second silicon carbide drift region comprises a fourth concentration of the first type dopant, the fourth concentration greater than the third concentration.

16. The semiconductor device of claim 15, wherein the fourth concentration of the first type dopant increases as the distance from the surface of the silicon carbide substrate increases.

17. The semiconductor device of claim 16 wherein the third silicon carbide drift region comprises a fifth concentration of the first type dopant, the fifth concentration greater than the fourth concentration.

18. The semiconductor device of claim 17, wherein the fifth concentration of the first type dopant increases as the distance from the surface of the silicon carbide substrate increases.

19. The semiconductor device of claim 18, wherein the first type dopant comprises an n-type dopant.

20. The semiconductor device of claim 18, wherein the first type dopant comprises a p-type dopant.
